(19) United States
(12) Patent Application Publication
(10) Pub. No.: US 2014/0317467 A1
(43) Pub. Date: Oct. 23, 2014

(54) METHOD OF DETECTING AND CORRECTING ERRORS WITH BCH ENGINES FOR FLASH STORAGE SYSTEM

(71) Applicant: STORART TECHNOLOGY CO., LTD., Hsinchu (TW)

(72) Inventors: CHIH-NAN YEN, Hsinchu (TW); Jui-Hui Hung, Hsinchu (TW); Hsueh-Chh Yang, Hsinchu (TW); Kai-Chih Chen, Hsinchu (TW)

(73) Assignee: Storart Technology Co., Ltd., Hsinchu (TW)

(21) Appl. No.: 13/867,126

(22) Filed: Apr. 22, 2013

(51) Int. Cl. H03M 13/15

(52) U.S. Cl. CPC H03M 13/152
USPC 714/758

(57) ABSTRACT

A method of detecting and correcting errors with BCH engines for flash storage system is provided and the steps of the method comprise: deciding the number i of sub-channels CH1˜CHi divided from a data channel; deriving a width selection of each sub-channel CHi; checking if the sum of width of each sub-channel CHi is equal to the data channel or not; if yes, run next step; if not, go back to the precious step; and connecting each BCH engine BCHi to each sub-channel CHi with a bus by one-by-one mapping.

### FIELD OF THE INVENTION

The present invention relates to a parallel combinational array of BCH(Rose, Ray-Chaudhuri, Hocquenghem) error detection/correction engines, and more particularly to a method of detecting and correcting errors with a parallel combinational array of BCH error detection/correction engines used to reduce the total chip die size effectively, comparing with single high-gate-density LDPC engine with the same correctable bits supported.

### BACKGROUND OF THE INVENTION

Flash memory is a popular storage media option in recent years. It is advantageous because it has lower power consumption, lower weight, and less cost, comparing to traditional magnetics hard drives. However, there may be some error bits in certain page(s) along with the access times of usage.

Along with the increase of bit density and multiple-layers manufacturing process of flash devices, the chance of having error bits inside certain flash page(s) is very high. For example, a typical TLC(triple-level cell) 64 G-bit flash might need 72-bit ECC(error correcting and checking) engine or higher and the bits demanded are increasing high for flash devices of next generation. Please refer to FIG. 1A, one LDPC engine 10 is connected to a data channel 20 via a bus 30, and the width of the LDPC engine 10 is equal to the width of the data channel 20. Therefore, more efficient and high-correction-bits detection/correction engines, such as LDPC engines(10, shown as FIG. 1A), are necessary for the new generation of flash devices to guarantee the data correctness when being stored in flash memory.

However, those new error detection/correction engines are usually much larger than original BCH ECC engines in terms of logic circuit size. Before better approaches are introduced to reduce the logic circuit size within the targeted correctable bits for new error detection/correction engine, IC designers have to allocate much more size than usual during the design stage for the flash control IC, which adversely affects gross margin. Thus, there remains a need for a new and improved error detection/correction engine to overcome the problems stated above.

### SUMMARY OF THE INVENTION

It is an objective of the present invention to provide combinational array of BCH error detection/correction engines to reduce die size by adopting a parallel combination of BCH detection/correction engines with lower error-correction-bits to achieve the same targeted correctable bits as a single LDPC engine does, and to improve the decoding/correction performance as well due to the parallelism architecture.

The power of error detection and correction of LDPC(low-density parity check) is based on predetermined probabilities of error distribution, i.e. a soft-decision approach, and so is this invention. Without processing the predetermined probabilities of error distribution, LDPC has almost the same error correction capability as BCH, but occupies more logic circuit area. Also, some error bits are still not correctable when adopting LDPC as the error detection/correction engine without processing the predetermined probabilities of error distribution.

The present invention has similar process of predetermined probabilities of error distribution as the soft decision of LDPC. The probabilities of error distribution is the segments being decoded, divided from the original channel and fed into BCH correction engines with lower correctable bits, have their own defined or targeted Bit Error Rate(“BER”), opposite to the original channel. Assuming the original channel is targeted at BER(CH_{whole}) bits and the separated sub-channels are targeted at BER(CH_{BCH0}) bits, BER(CH_{BCH1}) bits, BER(CH_{BCH2}) bits, BER(CH_{BCH3}) bits, and etc. The sum of the targeted correctable bits from each separated sub-channel equals original correctable bits cannot meet. It is usually greater than the demands of the original channel since the error bits distribution from original channel is not guaranteed to be divided uniformly among all separated sub-channels. (BER(CH_{whole})<BER(CH_{BCH0})+BER(CH_{BCH1})+BER(CH_{BCH2})+BER(CH_{BCH3}) is an additional requirement.)

The method of detecting and correcting errors with BCH engines for flash storage system in this invention is provided and the steps of the method comprise:
step S1: deciding the number i of sub-channels CH1˜CHi divided from an original channel;
step S2: deriving a width selection of each sub-channel CHi;
step S3: checking if the sum of width of each sub-channel CHi is equal to the original channel or not; if yes, run next step; if not, go back to the step S2; and
step S4: connecting each BCH engine BCHi to each sub-channel CHi with a bus by one-by-one mapping.

In some embodiments, the individual widths of each sub-channel CH1˜CHi may be identical, or the individual widths of each sub-channel CH1˜CHi may not be identical.

As long as the total size of logic circuit of error correction is reduced efficiently by any parallel combination of BCH correction engines and the original target can be met, the sum(final correctable bits) of correctable bits form each channel is no longer an important factor since the original channel has been divided into several channels.

According to parallel mechanism and lower correctable bit demand in each sub-channel, more efficient decoding time might be also introduced in this invention compared to the original channel with one LDPC. Therefore, better channel bandwidth or data rate would be expected.

### BRIEF DESCRIPTION OF THE DRAWINGS

FIG. 1A illustrates a schematic view of a conventional configuration with a single LDPC.

FIG. 1B illustrates a schematic view of an embodiment of parallel array of BCH error detection/correction engines. Any number and routing of those engines is up to a designer's choice to achieve the objective of size reduction.

FIG. 2 illustrates a schematic view of channel(s) division and the connection to BCH engines and LDPC engines with identical widths of the embodiment shown in FIG. 1B.

FIG. 3 illustrates a schematic view of channel(s) division and the connection to BCH engines and LDPC engines with different widths of the embodiment shown in FIG. 1B.

FIG. 4 illustrates a flow chart of a method of detecting and correcting errors with BCH engines for flash storage system in accordance with this invention.

### DESCRIPTION OF THE PREFERRED EMBODIMENT

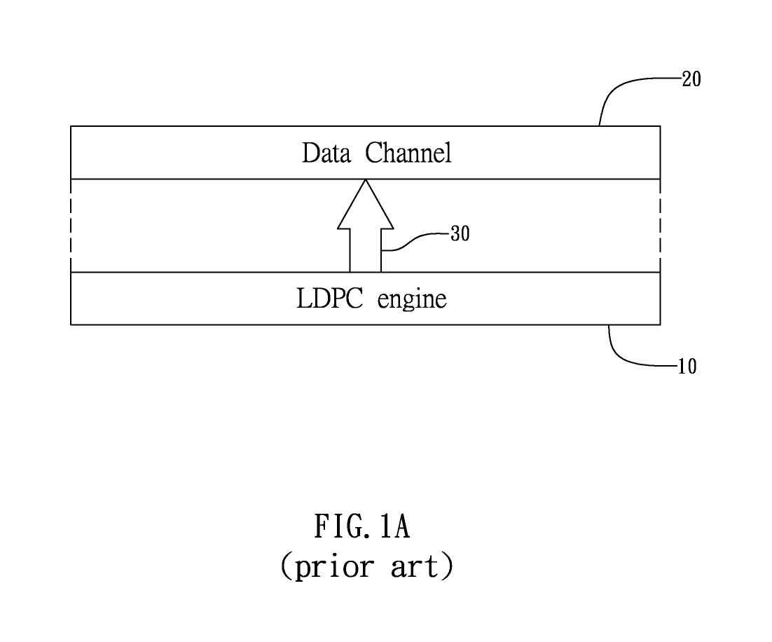

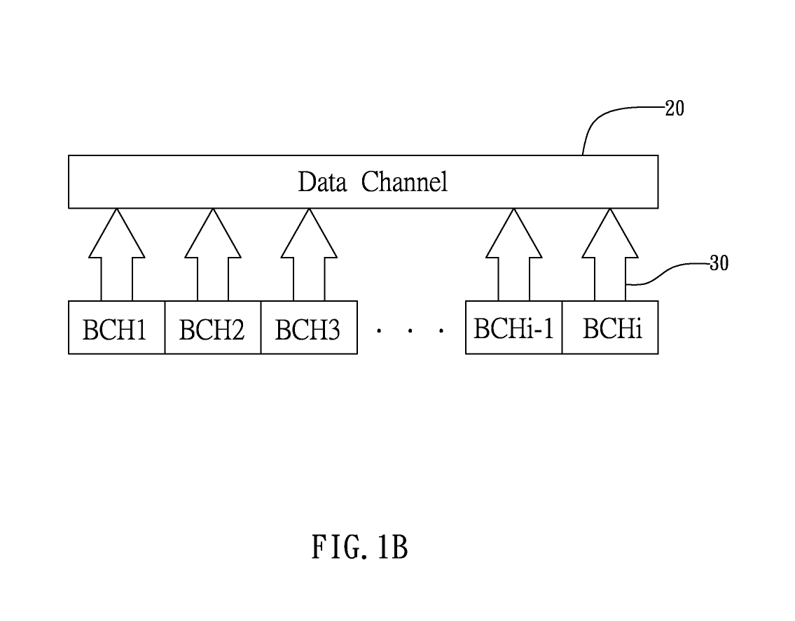

Please refer to FIG. 1B, which illustrates a schematic view of an example of parallel array of BCH error detection/correction engines. As shown in FIG. 1B, the data channel 20 may be divided in sub-channels CH1˜CHi, and the BCH (error detection/correction) engines BCH1˜BCHi are routed parallel as an array and connected to a data channel 20. There is no strict limit for the number and routing of those engines BCH1˜BCHi, except parallel to data sub-channels CH1˜CHi. The number and routing of the engine are up to a designer's decision. Besides, the number of the BCH engines is not limited, as long as the goal of effectively reducing the die size is achieved.

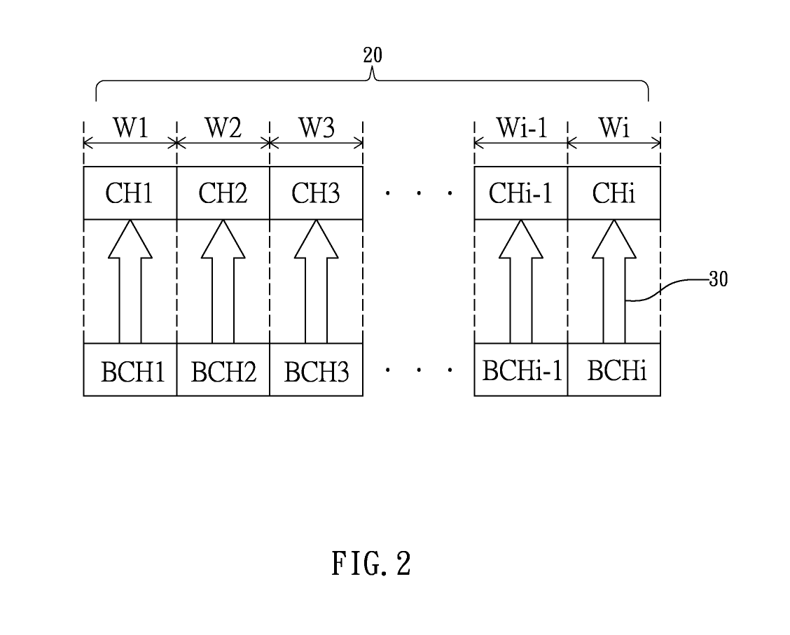

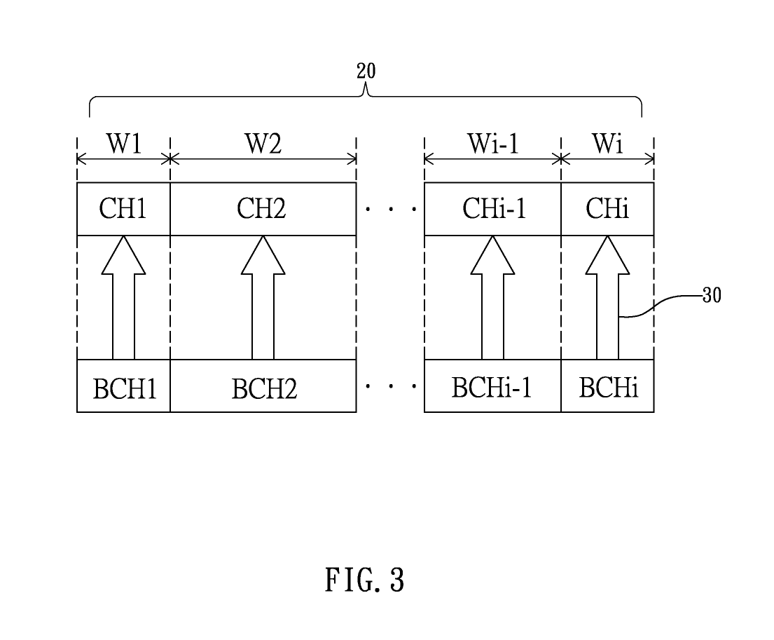

FIG. 2 illustrates a schematic view of channel(s) division and the connection to BCH engines and LDPC engines with identical widths of the embodiment shown in FIG. 1B. FIG. 3 illustrates a schematic view of channel(s) division and the connection to BCH engines and LDPC engines with different widths of the embodiment shown in FIG. 1B. This invent is not limited to be applied to single data channel and neither is one-by-one mapping. That is, each sub-channel CH1˜CHi is connected to each BCH engine BCH1˜BCHi with a bus 30 by one-by-one mapping. The width selection of each sub-channel CH1˜CHi is up to a designer's choice and the sum of each sub-channel must be equal to the width of original channel. And, the individual widths of sub-channels are not limited to be the same. That is, the individual widths W1˜Wi of each sub-channel CH1˜CHi may be identical (shown as FIG. 2), or the individual widths W1˜Wi of each sub-channel CH1˜CHi may not be identical (shown as FIG. 3). In addition, the widths of the sub-channel CHi and the corresponding BCH engine BCHi are the same.

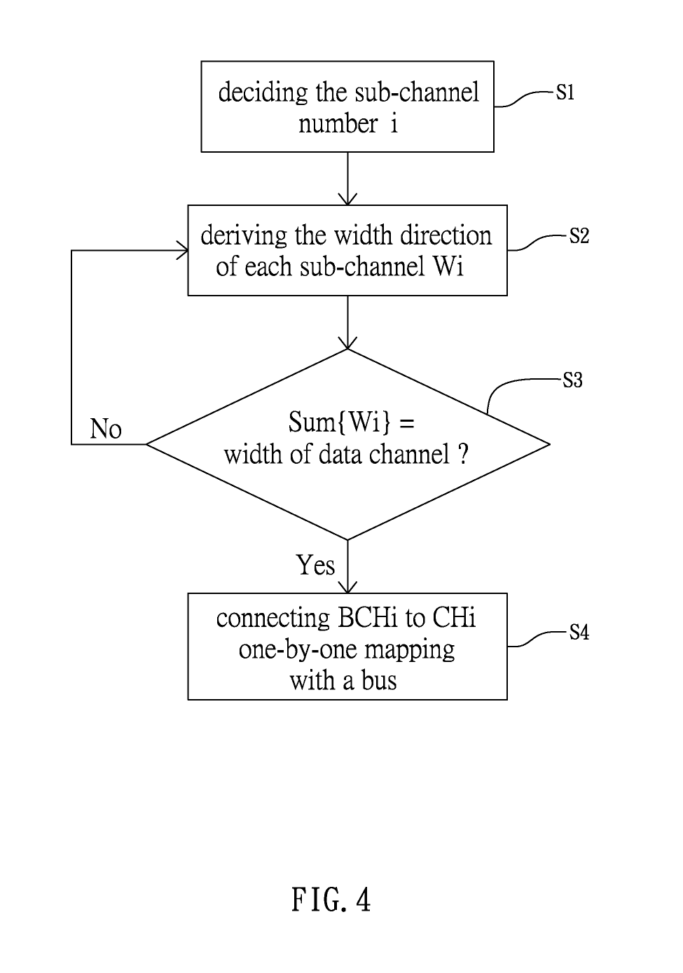

FIG. 4 illustrates a flow chart of a method of detecting and correcting errors with BCH engines for flash storage system in accordance with this invention. The steps of the method of detecting and correcting errors with BCH engines for flash storage system in this invention comprise as below. Step S1: deciding the number i of sub-channels CH1˜CHi divided from the data channel 20 depending on requirement. Step S2: deriving the width selection of each sub-channel CHi. Step S3: checking if the sum of width of each sub-channel CHi is equal to the length of the original channel 20 or not. If yes, run next step; if not, go back to the step S2 and try again. And step S4: connecting each BCH engine BCHi to each sub-channel CHi with a bus 30 by one-by-one mapping.

The number of the targeted correctable bits gathered from all sub-channels CH1˜CHi is not limited to be the targeted bits from the target of the original data channel 20, either. Usually, the sum of BER of all sub-channels CH1˜CHi is greater than the original data channel 20 since the channel division and non-uniform error bits distribution from original channel. More correctable bits and more channel widths might be required.

In addition, the supported correctable bits in each sub-channel CH1˜CHi are not limited to be the identical. Any combination is possible even though it is greater than original data channel 20.

Although the invention has been explained in relation to its preferred embodiment, it is not used to limit the invention. It is to be understood that many other possible modifications and variations can be made by those skilled in the art without departing from the spirit and scope of the invention as hereinafter claimed.

What is claimed is:

1. A method of detecting and correcting errors with BCH engines for flash storage system, the steps comprising:
step S1: deciding the number i of sub-channels CH1˜CHi divided from a data channel;
step S2: deriving a width selection of each sub-channel CHi;
step S3: checking if the sum of width of each sub-channel CHi is equal to the data channel or not; if yes, run next step; if not, go back to the step S2; and
step S4: connecting each BCH engine BCHi to each sub-channel CHi with a bus by one-by-one mapping.

2. The method as claimed in claim 1, wherein the widths of each sub-channel CH1˜CHi are identical.

3. The method as claimed in claim 1, wherein the widths of each sub-channel CH1˜CHi are not identical.

4. The method as claimed in claim 1, wherein the widths of the sub-channel CHi and the corresponding BCH engine BCHi are the same.
